(19) United States
(12) Patent Application Publication
(10) Pub. No.: US 2006/0063012 A1
(43) Pub. Date: Mar. 23, 2006

(54) Method for preparing low dielectric constant film by using dual organic siloxane precursor

(75) Inventors: Hyeon Jin Shin, Suwon-si (KR); Hyun Dam Jeong, Suwon-si (KR); Chi Kyu Choi, Jeju-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG CORNING CO., LTD., Suwon-si (KR)

(21) Appl. No.: 11/212,715

(22) Filed: Aug. 29, 2005

(30) Foreign Application Priority Data
Aug. 30, 2004 (KR) 10-2004-0068546

(51) Int. Cl. B32B 9/04; H01L 21/31; C08J 7/18; B05D 3/06

(52) U.S. Cl. 428/447; 428/448; 438/778; 427/489; 427/588

(57) ABSTRACT

A method for preparing a dielectric film. According to the method, a dielectric film is prepared by depositing a dual organic siloxane precursor on a wafer by plasma enhanced chemical vapor deposition (PECVD). Since a dielectric film prepared by the method has a low dielectric constant and shows superior physical properties, such as elastic modulus and hardness, it can be useful as an interlayer dielectric film for a semiconductor device for dual damascene copper interconnects or as a passivation layer for semiconductor and display devices.

This non-provisional application claims priority under 35 U.S.C. § 119(a) on Korean Patent Application No. 2004-68546 filed on Aug. 30, 2004, which is herein incorporated by reference.

### BACKGROUND OF THE INVENTION

1. Field of the Invention

Embodiments of the present invention relate to a method for preparing a dielectric film, and more particularly to a method for preparing a low dielectric constant (low-κ) film having a high mechanical strength by depositing a dual organic siloxane precursor on a wafer by plasma enhanced chemical vapor deposition (hereinafter, abbreviated as “PECVD”).

2. Description of the Related Art

Since Cu-chips developed by IBM were applied to power PC740/750 devices, large investment has been made in the development of low dielectric constant materials which can be applied to multilayer wiring structures by many enterprises, including Power Micronics and Motorola, and research institutes. Further, vast sums of money have been invested in the development of low dielectric constant thin films and preparation equipment. In particular, the National Technology Roadmap for Semiconductor (NTRS), American Semiconductor Industry Association, reported in 1997 that a low dielectric constant material having a dielectric constant of 2.5-3.0 is required to apply the copper-chips developed by IBM to 0.18 μm devices, and a low dielectric constant material having a dielectric constant of 2.0-2.5 is required to apply the chips to 0.15 μm devices.

Since conventional low dielectric constant materials, particularly SiO₂, have problems in terms of their high dielectric constant, a great deal of research has been conducted on organic•inorganic low dielectric constant materials, for example, polyimides, poly(arylene)ethers, and polytetrafluoroethylenes (PTFE).

Although polyimides have advantages in general physical properties, including heat resistance (>550° C.), dielectric properties (e.g., dielectric constant: 2.6-3.5), mechanical strength, chemical resistance, etc., compared to other polymers, there is a drawback of a high moisture absorption (1.5%).

Further, poly(arylene)ether commercially available from Allied Signal Corp. under the trademark Flare has a relatively high chemical stability, a low moisture absorption (0.4%) due to its chemical structure, excellent crack resistance, and superior thermal and mechanical stability. However, disadvantages of the poly(arylene)ether are that the chemical mechanical polishing (CMP) characteristics are poor when compared to inorganic thin films, and the adhesion is poor as the fluorine content increases.

On the other hand, NEC (Japan) prepared fluorinated amorphous carbon (a:C-F) thin films from fluorinated compounds, such as C₂F₆, C₄F₈ and CF₄, by high-density PECVD, measured the dielectric constant, thermal properties and mechanical properties of the thin films, and reported that the thin films can be utilized as interlayer insulating materials of multilayer wirings. According to the results of the report, the thin films have a low dielectric constant of about 2.1, are suitable for CMP processes, and show superior physical properties, but they are poor in thermal properties.

In recent years, a number of studies on the formation of a nanoporous, low dielectric constant thin film have been actively undertaken. TI and Nanoglass companies reported that when nanoporous silica xerogels made by a sol-gel process had a porosity of 80%, the dielectric constant reached 1.8. According to this report, when nanoglass with a dielectric constant of 1.3-2.5 was applied to a single damascene structure having a line width of 0.3 μm, a significant reduction (−36%) in capacity was achieved.

On the other hand, IBM has succeeded in preparing nanoporous silicas that have a dielectric constant of 2.0 or less, high thermal stability, reduced moisture absorption, excellent crack resistance, and superior adhesion to liner and cap materials by nanophase phase separation using an organosilicate and a special shape polymer (star, dendrimer, hyperbranched type). However, these nanoporous silicas suffer from a low mechanical strength (particularly, hardness) unsuitable for CMP, a deterioration in properties upon heat treatment, and various problems caused during etching, resulting in difficulties in fabricating devices.

To solve the above-mentioned problems, many studies have been devoted to a nanoporous organic•inorganic compound prepared by ring linkage in an SiOC(—H) thin film, which is formed by incorporating carbon atoms into a conventional SiO₂ material. Such organic•inorganic compounds have a low dielectric constant (κ<3.0). It has been determined that so long as an interlayer dielectric film for a semiconductor device does not have a nanoporous structure, a low dielectric constant of 2.5 or less cannot be achieved. Under this circumstance, a great deal of research has been conducted on the development of a low dielectric constant material (e.g., BLACK DIAMOND™, which is a low dielectric constant material made of SiOC(—H)) and the application of a nanoporous thin film to an interlayer dielectric film for a semiconductor device.

As described above, various methods for preparing low dielectric constant thin films have been introduced to date. However, as the dielectric constant of these thin films decreases, deterioration in mechanical properties is caused, which is a serious impediment to the fabrication of devices. Since currently used precursors have a single silicon structure within one molecule, they cannot simultaneously satisfy the requirements of low dielectric constant and superior mechanical properties. That is, when dielectric films prepared using the precursors have a low dielectric constant (κ=2.5-3.0), they are poor in mechanical properties (e.g., elastic modulus=8-12 GPa). On the other hand, when the dielectric films are superior in mechanical properties (e.g., elastic modulus=60-80 GPa), they have a high dielectric constant (κ=3.8-4.0).

On the other hand, chemical vapor deposition (hereinafter, referred to as “CVD”) and spin-on deposition (SOD) are currently used to prepare dielectric films. Thin films prepared by spin-on deposition have poor performance compared to those prepared by CVD. Further, since thin film deposition and etching are carried out in in-line mode in the fabrication processes of semiconductor devices, PECVD is mainly adopted in above 60% of the fabrication processes. Moreover, PECVD can be carried out even at low temperatures, whereas SOD using a SiOC compound is difficult to carry out at low temperatures. Accordingly, PECVD can be advantageously used to prepare a dielectric film by using an organic•inorganic compound having an organic siloxane structure.

Thus, there is a need in the art to develop a novel precursor material usable to prepare a dielectric film by CVD, and enabling a dielectric film to have a low dielectric constant, superior mechanical properties, such as elastic modulus, and greatly improved applicability to semiconductor processes.

### OBJECTS AND SUMMARY

Embodiments of the present invention are based on the findings that a dielectric film prepared by depositing a compound having a specific structure, particularly, a dual organic siloxane compound containing two different silicon moieties within one molecule, on a wafer by means of PECVD shows superior physical properties, such as elastic modulus and hardness, thermal stability and crack resistance, and hence the dielectric film can be used as an interlayer dielectric film for a semiconductor device for dual damascene copper interconnects or as a passivation layer for semiconductor and display devices.

Therefore, a feature of embodiments of the present invention is to provide a method for preparing a dielectric film with superior mechanical properties.

Another feature of embodiments of the present invention is to provide a dielectric film that can be used as an interlayer dielectric film for a semiconductor device for dual damascene copper interconnects or as a passivation layer for semiconductor and display devices.

In accordance with one aspect of embodiments of the present invention, there is provided a method for preparing a dielectric film with a low dielectric constant and a high mechanical strength by depositing a dual organic siloxane precursor on a wafer by PECVD.

In accordance with another aspect of embodiments of the present invention, there is provided a dielectric film prepared by the method, the dielectric film having a low dielectric constant and superior mechanical properties, such as elastic modulus and hardness, and being usable as an interlayer dielectric film for a semiconductor device for dual damascene copper interconnects or as a passivation layer for semiconductor and display devices.

### BRIEF DESCRIPTION OF THE DRAWINGS

The above and other objects, features and other advantages of embodiments of the present invention will be more clearly understood from the following detailed description taken in conjunction with the accompanying drawings, in which:

FIG. 1 is a schematic view of an apparatus for preparing a dielectric film by using a dual organic siloxane precursor;

FIG. 2 is a graph showing Fourier transform infrared spectroscopy (FTIR) spectra of dielectric films prepared in Examples 1 to 3;

FIG. 3 shows X-ray photoelectron spectra (XPS) of a dielectric film prepared according to one embodiment of the present invention, demonstrating the constitution of the dielectric film;

FIG. 4 shows field emission scanning electron micrographs (FESEMs) of a dielectric film prepared according to one embodiment of the present invention, demonstrating the dot size and thickness of the dielectric film, and a graph showing the capacitance (C)-voltage (V) characteristics of the dielectric film; and

FIG. 5 is a plot of displacement into surface versus elastic modulus and hardness of a dielectric film prepared according to one embodiment of the present invention.

### DETAILED DESCRIPTION OF THE PREFERRED EMBODIMENTS

Embodiments of the present invention will now be described in more detail.

Referring to FIG. 1, a dielectric film may be prepared by depositing a mixture of a dual organic siloxane precursor and a film property modifier on a wafer by means of PECVD.

The term “dual organic siloxane precursor” as used herein refers to a cyclic organic siloxane precursor wherein a Si moiety (Si—O—Si) is formed as a backbone at the core position, and same or different silicon (Si)-containing reactive groups are bonded to the Si moiety at terminal positions of the backbone.

The dual organic siloxane precursor used in a method according to embodiments of the present invention may be represented by Formula 1 below:

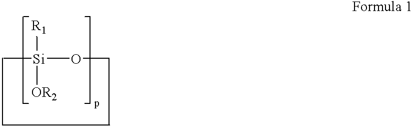

wherein R₁ is a hydrogen atom, a C₁₋₃alkyl group, or a C₆₋₁₅ aryl group; R₂ is SiX₁X₂X₃ (in which X₁, X₂, and X₃ are independently a hydrogen atom, a C₁₋₃ alkyl group, a C₁₋₁₀ alkoxy group, or a halogen atom); and p is a number of 3 to 8.

Specific examples of the compound of Formula 1 include compounds represented by Formulae 2 to 5 below:

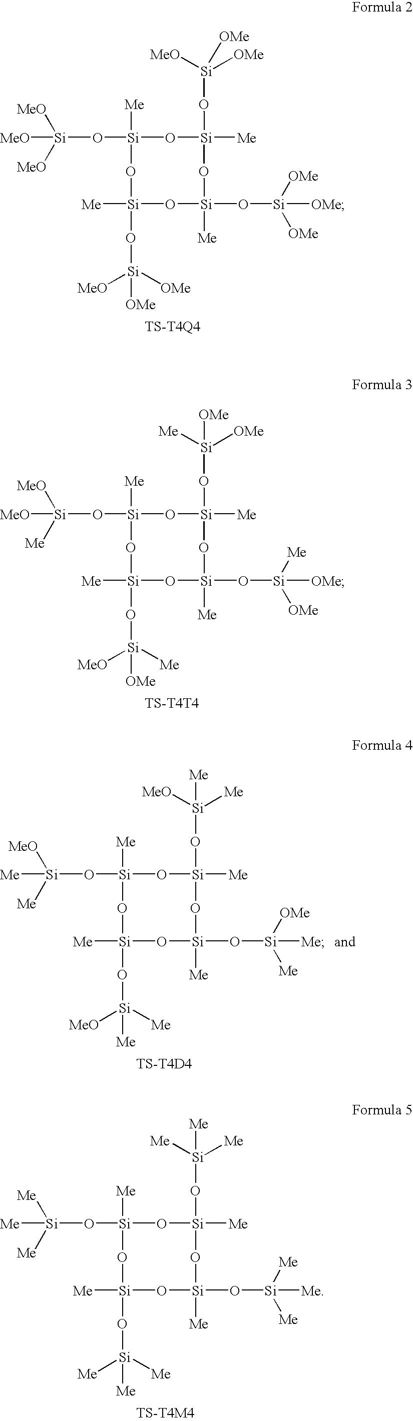

On the other hand, methyltrimethoxysilane (hereinafter referred to as “MTMS”) is a single organic siloxane precursor which has been used in the preparation of dielectric films by conventional CVD, and is represented by Formula 6 below:

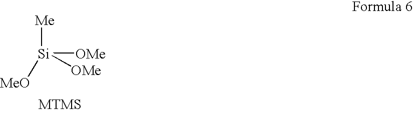

Hereinafter, the dual organic siloxane precursors of Formulae 2 to 5 used in a method of embodiments of the present invention will be compared with the single organic siloxane precursor of Formula 6.

Conventional single organic siloxane precursors, including the precursor of Formula 6, are represented by the following symbols: “Q”; “T”; “D”; and “M”. When the number of Si—O bond(s) in a single organic siloxane precursor is four, three, two, and one, the symbol is designated as “Q”, “T”, “D”, and “M”, reflecting quadri-, tri-, di-, and mono-, respectively. The chemical properties of single organic siloxane precursors vary depending on the configuration of Si—O bond(s). As the structure “Q” shifts to the structure “M”, the free volume of Si—CH₃ moiety increases, resulting in a low dielectric constant, an increased toughness, a decreased elastic modulus, and a decreased hardness. The MTMS of Formula 6 is represented by structure “T” and is predominantly used as a single organic siloxane precursor simultaneously satisfying the above-mentioned chemical properties. In addition, the single organic siloxane precursors have advantages of low molecular weight and boiling point, but have disadvantages in that the structure of thin films to be formed is difficult to predict and is largely dependent on the structure of selected precursors.

In contrast to single organic siloxane precursors, the dual organic siloxane precursors of Formulae 2 to 5 have relatively high molecular weight and boiling point. However, since these precursors have a condensed Si—O—Si-moiety as a backbone within their molecular structure, the physical properties of thin films prepared therefrom are dependent not only on the Si structures (i.e., structures Q/T/D/M), but also on the structure of selected monomers, so long as the structure of the monomers is maintained during formation of thin films. In addition, since active sites in the two structures (i.e., structures T & Q/T/D/M) are present at terminal positions, there is an advantage in that the characteristics of the dual organic siloxane precursors are easy to control.

Based on these advantages, the compounds of Formulae 2 to 5 may be used for the preparation of a dielectric film in embodiments of the present invention. The dielectric film thus prepared has a low dielectric constant and superior mechanical properties.

A film property modifier used for the preparation of a dielectric film in embodiments of the present invention may be a gas added for the purpose of controlling the carbon content of the thin film. As the film property modifier, there may be mentioned O₂, CH₄, Xe, and other film properly modifiers known to those skilled in the art. O₂ is preferred.

The content of the dual organic siloxane precursor used for the preparation of a dielectric film may be 10% or more, but not exceeding 100%, and is preferably 70% or more, but not exceeding 100%, based on the total amount of the dual organic siloxane precursor and the film property modifier. This is because the content of the film property modifier causes changes in the dielectric constant of a dielectric film.

A dielectric film may be prepared in accordance with the following procedure. First, the dual organic siloxane precursor and the film property modifier are mixed. Thereafter, the mixture is deposited on a wafer by PECVD under a pressure of about 0.5 torr to about 2 torr at a ratio frequency (RF) power of 100-800W for 1-10 minutes while maintaining a bubbler temperature at 90-300° C. and a gap between the wafer and a head shower at 1-8 cm, to prepare the final dielectric film. After the deposition, a post-processing step, e.g., heating, UV irradiation, electron beam-irradiation or plasma treatment, can be carried out.

Generally, a dielectric film is formed on top of a semiconductor device in order to protect the electrical properties of the device against chemical reactions or corrosion and to prevent the performance of the device from being deteriorated when exposed to air after fabrication of the device. Since this passivation layer should have superior chemical resistance, crack resistance, wear resistance, thermal stability, and the like, it should be formed at a thickness of at least 3 μm. A passivation layer prepared using a conventional single organic siloxane precursor by spin coating is limited to a thickness of 2 μm or less. Above 2 μm, cracks are likely to occur. In contrast, a dielectric film prepared using a dual organic siloxane precursor by PECVD in embodiments of the present invention may have a thickness of 3 μm or more. Accordingly, a dielectric film prepared using a dual organic siloxane precursor may be used as a passivation layer for a semiconductor device.

Further, a dielectric film prepared by a method of embodiments of the present invention may be used as a passivation layer for a display device. A general display device displays visual information on a 2-dimensional plane using chemical and physical phenomena in response to electrical signals. The display of visual information is achieved by orientation of liquid crystal molecules or by electrical control of luminescence from organic and inorganic compounds. To electrically control the chemical and physical behaviors of organic and inorganic compounds in a stable manner, the organic and inorganic compounds should be stable against chemical deformation and corrosion in a state where electrical power is dissipated. Accordingly, a dielectric film prepared by a method of embodiments of the present invention may be formed as a passivation layer for a display device during or after fabrication of the display device.

Embodiments of the present invention will now be described in more detail with reference to the following preparative examples, examples, and comparative examples. However, these examples are given for the purpose of illustration and are not to be construed as limiting the scope of the invention.

Preparation of Dual Organic Siloxane Precursors

### PREPARATIVE EXAMPLE 1

### Preparation of Monomer (A-1) (TS-T4Q4)

41.6 mmole (10.00 g) of 2,4,6,8-tetramethyl-2,4,6,8-cyclotetrasiloxane was placed into a flask, and then 100 ml of tetrahydrofuran was added thereto to prepare a dilution. 700 mg of 10 wt % palladium/charcoal (Pd/C) was added to the dilution, followed by the addition of 177.8 mmol (3.20 ml) of distilled water. At this time, hydrogen gas evolved during the addition was removed. The resulting mixture was allowed to react at room temperature for 5 hours. The reaction solution was filtered through celite and MgSO₄, and diluted in 200 ml of tetrahydrofuran. To the dilution was added 177.8 mmol (13.83 g) of triethylamine. After the resulting solution was cooled to 0° C., 177.8 mmol (25.0 g) of chlorotrimethoxysilane was slowly added. The temperature was slowly elevated to room temperature. The reaction was allowed to proceed for 12 hours. The reaction solution was filtered through celite, and the obtained filtrate was concentrated at a reduced pressure (approximately 0.1 torr) to remove volatile substances, affording the monomer (A-1) of Formula 3 as a colorless liquid.

The analytical results of the ¹H-NMR spectrum (acetone-d₆, 300 MHz) of the monomer (A-1) are as follows: δ0.12 (s, 12H, 4×[—CH₃]), 0.24 (s, 12H, 4×[—CH₃]), 3.53 (s, 24H, 4×[—OCH₃]₂).

### PREPARATIVE EXAMPLE 2

### Preparation of Monomer (A-2) (TS-T4T4)

The compound of Formula 4 [hereinafter, referred to as (A-2)] was prepared in the same manner as in Preparative Example 1, except that chloromethyldimethoxysilane was used instead of chlorotrimethoxysilane.

The analytical results of the ¹H-NMR spectrum (acetone-d₆, 300 MHz) of the monomer (A-2) are as follows: δ0.092 (s, 12H, 4×[—CH₃]), 3.58 (s, 36H, 4×[—OCH₃]₃).

### PREPARATIVE EXAMPLE 3

### Preparation of Monomer (A-3) (TS-T4D4)

The compound of Formula 5 [hereinafter, referred to as (A-3)] was prepared in the same manner as in Preparative Example 1, except that chlorodimethylmethoxysilane was used instead of chlorotrimethoxysilane.

The analytical results of the ¹H-NMR spectrum (acetone-d₆, 300 MHz) of the monomer (A-3) are as follows: δ0.068 (s, 24H, 4×[—CH₃]₂), 0.092 (s, 12H, 4×[—CH₃]), 3.58 (s, 12H, 4×[—OCH₃]).

### PREPARATIVE EXAMPLE 4

### Preparation of Monomer (A-4) (TS-T4M4)

The compound of Formula 6 [hereinafter, referred to as (A4)] was prepared in the same manner as in Preparative Example 1, except that chlorotrimethylsilane was used instead of chlorotrimethoxysilane.

The analytical results of the ¹H-NMR spectrum (acetone-d₆, 300 MHz) of the monomer (A4) are as follows: δ0.059 (s, 36H, 4×[—CH₃]₃), 0.092 (s, 12H, 4×[—CH₃]).

Preparation of Dielectric Films

### EXAMPLE 1(A)

FIG. 1 is a schematic view of an apparatus for preparing a low dielectric constant film by using the dual organic siloxane precursor in accordance with a method of embodiments of the present invention. Referring to FIG. 1, a method for preparing a dielectric film by using the dual organic siloxane precursor prepared in Preparative Example 3 will be explained.

A mixture of the dual organic siloxane precursor (TS-T4D4) prepared in Preparative Example 3 and O₂ were deposited on p-type Si wafers with a radio-frequency (RF) power of 13.56 MHz by PECVD. No heating was applied to the wafers while maintaining an earth potential. The wafers were completely cleaned in accordance with the standard cleaning procedure before being mounted on a reaction chamber. Plasma was generated by a three-turn coil arranged around a quartz tube. An initial pressure before deposition was set to 10⁶ torr. The TS-T4D4 used herein is a non-toxic, colorless liquid with a boiling point of 255° C. under atmospheric pressure. All gas lines were heated so that TS-T4D4 in a vaporized state was not re-condensed and a bubbler temperature was maintained at 90° C. The flow ratio of the TS-T4D4 to the O₂ was adjusted to 100:0 (The total flow rate was 100 sccm). The deposition pressure was adjusted to 570 mTorr. Under these conditions, deposition was carried out with a fixed RF power of 700 W for 5 minutes without heating the wafers to prepare a dielectric film. For comparison of thermal stability, the dielectric film was subjected to annealing under 10⁶ torr at 400° C. for 30 minutes.

### EXAMPLE 2(B)

A dielectric film was prepared in the same manner as in Example 1, except that the flow ratio (TS-T4D4: O₂) was changed to 90:10 and the deposition pressure was changed to 650 mTorr.

### EXAMPLE 3(C)

A dielectric film was prepared in the same manner as in Example 1, except that the flow ratio (TS-T4D4: O₂) was changed to 70:30 and the deposition pressure was changed to 750 mTorr.

### COMPARATIVE EXAMPLE 1(D)

A dielectric film was prepared in the same manner as in Examples 1 to 3, except that methyltrimethoxysilane (MTMS) was used instead of TS-T4D4, the flow ratio (MTMS : O₂) was adjusted to 100:0 (the total flow rate was 100 sccm), the deposition pressure was adjusted to 10² mTorr, and deposition was carried out with a fixed RF power of 300 W without heating the wafers.

### COMPARATIVE EXAMPLE 2(E)

A dielectric film was prepared in the same manner as in Comparative Example 1, except that the flow ratio (MTMS: O₂) was changed to 92:8 and the deposition pressure was changed to 10³ mTorr.

### COMPARATIVE EXAMPLE 3(F)

A dielectric film was prepared in the same manner as in Comparative Example 1, except that the flow ratio (MTMS: O₂) was changed to 83:17 and the deposition pressure was changed to 10² mTorr.

Performance Analysis of Dielectric Films

The performances of the dielectric films prepared in Examples 1-3 and Comparative Examples 1-3 were measured by the following procedures, and were compared.

1) Measurement of Thickness, Dielectric Constant and Refractive Index

A dielectric film is formed on a boron-doped p-type silicon wafer, and then a 5,000 Å thick aluminum thin film is formed on the dielectric film using a hardmask designed so as to have electrode diameters of 0.25/0.50/0.75 mm, to form a metal-insulator-metal (MIM)-structured low dielectric constant thin film for dielectric constant measurement. The C-V characteristics for the thin film are measured while applied voltages are swept from −50 V to 50 V. Changes in the capacitance and dielectric loss of the thin film according to the changes in applied voltage and frequency are measured between —10 V and 10 V. Voltages applied to measure the dielectric constant of the thin film are measured at 1 MHz. The thickness and refractive index of the thin film are measured using an ellipsometer, and the measured thickness of the thin film is determined by field emission scanning electron microscopy (FESEM). The dielectric constant of the thin film is calculated according to the following equation:
κ=C×d/ε₀×A
in which κ is the relative permittivity, C is the capacitance of the dielectric film, εₒ is the dielectric constant of a vacuum (8.8542×10⁻¹² Fm⁻¹), d is the thickness of the dielectric film, and A is the contact cross-sectional area of the electrode.

2) Mechanical Properties (Hardness and Elastic Modulus)

The hardness and elastic modulus of a dielectric film are determined by quantitative analysis using a Nanoindenter II (MTS). Nanoindentation technique is used to measure the mechanical properties of a thin film by deforming the thin film using a sharp indenter while pressing the sharp indenter to a depth of a few micrometers under a very small load. Specifically, after the nanoindenter is indented into the thin film until the indentation depth reaches 10% of the overall thickness of the thin film, the hardness and modulus of the thin film are measured. In order to ensure better reliability of these measurements in Examples 1-3 and Comparative Examples 1-3, the hardness and modulus are measured at a total of 9 indentation points on the dielectric film, and the obtained values are averaged.

Table 1 shows the measurement results for the thickness, refractive index, dielectric constant, elastic modulus and hardness of the dielectric films prepared in Examples 1-3 (A, B and C) and Comparative Examples 1-3 (D, E and F) in accordance with the respective procedures, and shows the changes in the dielectric constant and physical properties measured before (A to F) and after annealing (A′ to F′) under different deposition conditions.

TABLE 1

| | TS-T4D4:O₂ | Thickness | Refractive | Dielectric | Elastic | |
|---|---|---|---|---|---|---|
| | (or MTMS:O₂) | (Å) | index | constant (κ) | modulus | Hardness |
| Before | 100:0 (A) | 3625 | 1.619 | 2.94 | 48.88 | 4.46 |
| annealing | 90:10 (B) | 3104 | 1.594 | 2.83 | 63.46 | 6.95 |
| | 70:30 (C) | 3164 | 1.592 | 2.67 | 21.26 | 2.42 |
| | 100:0 (D) | 4000 | 1.500 | 2.55 | 13.98 | 1.98 |
| | 92:8 (E) | 4000 | 1.466 | 2.76 | 16.77 | 2.53 |
| | 83:17 (F) | 4000 | 1.470 | 2.95 | 17.28 | 2.57 |
| After | 100:0 (A′) | 2604 | 1.620 | 2.90 | 47.95 | 4.30 |
| annealing | 90:10 (B′) | 3814 | 1.576 | 2.83 | 63.80 | 7.06 |
| | 70:30 (C′) | 3328 | 1.540 | 2.76 | 27.98 | 2.52 |
| | 100:0 (D′) | 4000 | 1.470 | 2.50 | 9.48 | 0.63 |
| | 92:8 (E′) | 4000 | 1.475 | 2.75 | 10.01 | 0.65 |
| | 83:17 (F′) | 4000 | 1.550 | 2.99 | 12.64 | 0.98 |

As can be seen from the data shown in Table 1, the dielectric constant of the TS-T4D4 dielectric films prepared in Examples 1-3 and the conventional MTMS dielectric films prepared in Comparative Examples 1-3 can be easily controlled by controlling the content of O₂. The dielectric films prepared in Examples 1 and 2 have higher elastic modulus values (48.88 and 63.46, respectively) than the MTMS dielectric film (16.77). Further, the dielectric films prepared in Examples 1 and 2 have higher hardness values (4.46 and 6.95, respectively) than the MTMS dielectric film (2.53). From these results, it can be confirmed that the mechanical properties of the dielectric films prepared in Examples 1-3 are superior to those of the conventional MTMS dielectric film. This fact becomes evident from FIG. 5. FIG. 5 shows a plot of displacement into surface versus elastic modulus and hardness of the TS-T4D4 dielectric film. As apparent from FIG. 5, the TS-T4D4 dielectric film has high elastic modulus and hardness values.

Further, there is no significant difference in the elastic modulus and hardness values of the dielectric films prepared in Examples 1-3 measured before and after annealing. However, the elastic modulus and hardness of the conventional MTMS dielectric film prepared in Comparative Example 2 measured after annealing (10.01, 0.65) are much lower than those before annealing (16.77 and 2.53, respectively). In summary, the TS-T4D4 dielectric films prepared in Examples 1-3 are superior in mechanical properties and stability against annealing to the conventional MTMS dielectric films. In the same dielectric constant range (2.7<κ<2.8), the TS-T4D4 dielectric film has a higher elastic modulus value than the MTMS dielectric film. These results are thought to be due to the difference in the structures of the organic siloxane precursors (i.e., dual structure and single structure) rather than due to the dependency on the deposition apparatus.

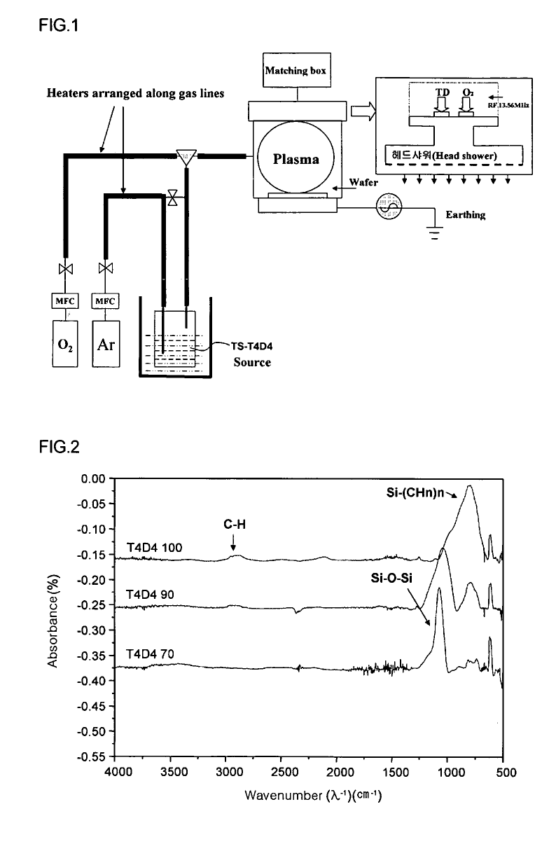

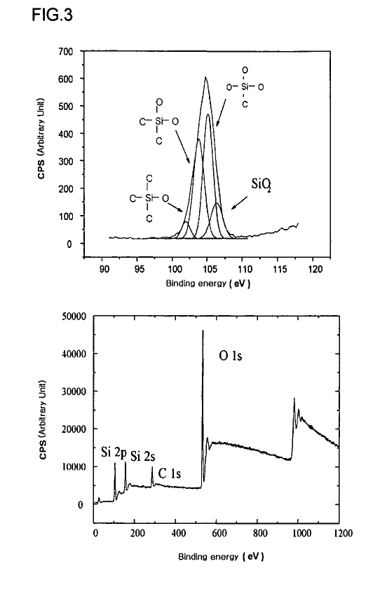

FIG. 2 is a graph showing Fourier transform infrared spectroscopy (FTIR) spectra of the dielectric films prepared in Examples 1 to 3, and FIG. 3 shows X-ray photoelectron spectra (XPS) of a dielectric film prepared according to one embodiment of the present invention, demonstrating the constitution of the dielectric film. As shown in FIG. 3, the binding energy values of SiO₃C (T) and SiO₂C₂ (D) in the TS-T4D4 structure are higher than those of SiO₂ (Q) and SiOC₃ (M). Details regarding the proportions of binding energy values are shown in Table 2 below.

TABLE 2
Binding Energy Values

| TS-T4D4:O₂ | SiO₂ (Q) | SiO₃C (T) | SiO₂C₂ (D) | SiOC₂ (M) |
|---|---|---|---|---|
| 100:0 | 18.2 | 40.4 | 34.2 | 7.2 |
| 90:10 | 14.6 | 42.4 | 37.8 | 5.2 |

It can be inferred from the data shown in Table 2 that when the O₂ content is 10% and a dual organic siloxane precursor having higher T and D contents is used, optimal performance of a dielectric film can be achieved.

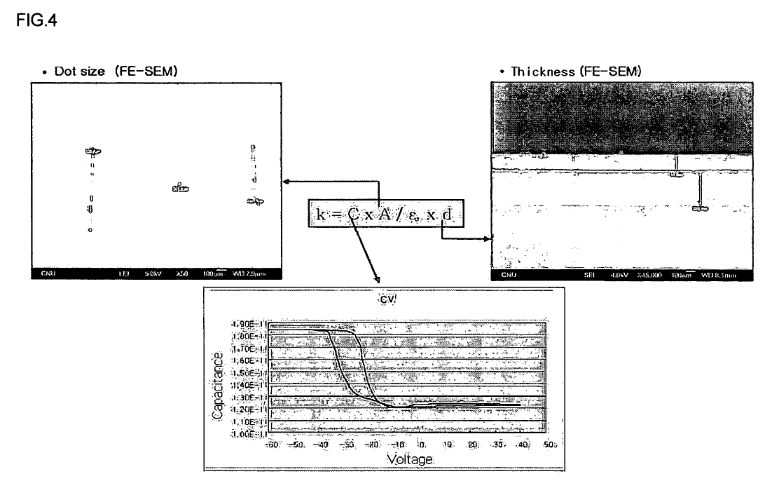

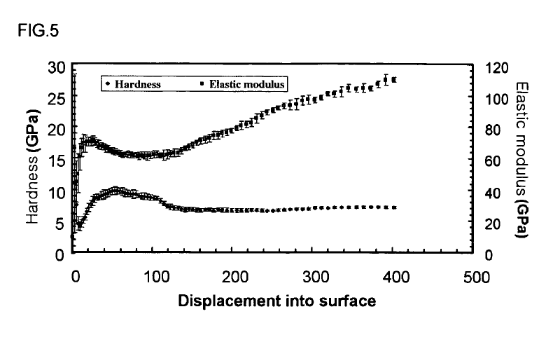

FIG. 4 shows field emission scanning electron micrographs (FESEMs) of a dielectric film prepared by a method of embodiments of the present invention, demonstrating the dot size and thickness of the dielectric film, and a graph showing the capacitance (C)-voltage (V) characteristics of the dielectric film.

As apparent from the foregoing, a dielectric film prepared using a dual organic siloxane precursor by a method of embodiments of the present invention not only has a low dielectric constant, but also shows superior mechanical properties, such as elastic modulus and hardness. In addition, the dielectric film shows superior thermal stability. Therefore, the dielectric film has greatly improved applicability to semiconductor processes, and hence the dielectric film can be used as an interlayer dielectric film for a semiconductor device for dual damascene copper interconnects or as a passivation layer for semiconductor and display devices.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for preparing a dielectric film comprising:
depositing a mixture of a dual organic siloxane precursor and a film property modifier on a wafer by plasma enhanced chemical vapor deposition.

2. The method according to claim 1, wherein the dual organic siloxane precursor is a compound represented by Formula 1 below: 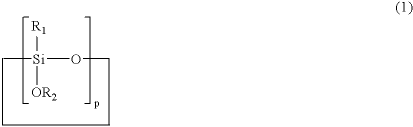
wherein R₁ is a hydrogen atom, a C₁₋₃alkyl group, or a C₆₋₁₅ aryl group; R₂ is SiX₁X₂X₃, in which X₁, X₂, and X₃ are independently a hydrogen atom, a C₁₋₃ alkyl group, a C₁₋₁₀ alkoxy group, or a halogen atom; and p is a number of 3 to 8.

3. The method according to claim 1, wherein the film property modifier is O₂, CH₄, or Xe.

4. The method according to claim 2, wherein the film property modifier is O₂, CH₄, or Xe.

5. The method according to claim 1, wherein the dual organic siloxane precursor is present in an amount of 10% to 100%, based on the total amount of the dual organic siloxane precursor and the film property modifier.

6. The method according to claim 2, wherein the dual organic siloxane precursor is present in an amount of 10% to 100%, based on the total amount of the dual organic siloxane precursor and the film property modifier.

7. The method according to claim 1, wherein the plasma enhanced chemical vapor deposition is carried out under a pressure of 0.5-2 torr at a radio frequency power of 100-800 W.

8. The method according to claim 2, wherein the plasma enhanced chemical vapor deposition is carried out under a pressure of 0.5-2 torr at a radio frequency power of 100-800 W.

9. The method according to claim 1, wherein the dielectric film is deposited to a thickness of at least 3 μm.

10. The method according to claim 2, wherein the dielectric film is deposited to a thickness of at least 3 μm.

11. The method according to claim 1, further comprising heating, UV irradiation, electron beam-irradiation, or plasma treatment of the dielectric film.

12. The method according to claim 2, further comprising heating, UV irradiation, electron beam-irradiation, or plasma treatment of the dielectric film.

13. The method according to claim 2, wherein the dual organic siloxane precursor of Formula 1 is selected from the group consisting of compounds represented by Formulae 2 to 5 below:

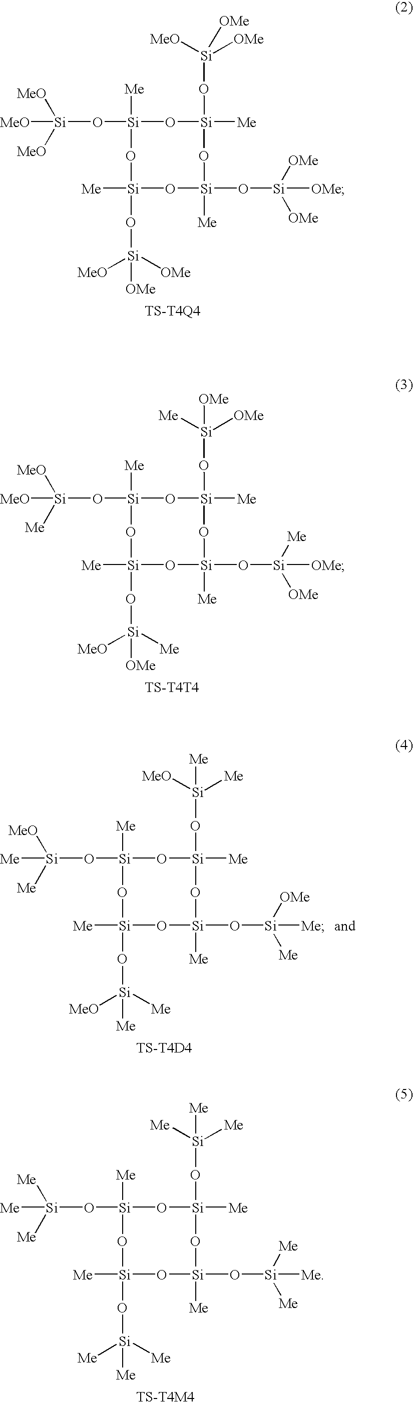

14. A dielectric film prepared by the method according to claim 1.

15. A dielectric film prepared by the method according to claim 2.

16. The dielectric film according to claim 14, wherein the dielectric film is a passivation layer for semiconductor and display devices.

17. The dielectric film according to claim 15, wherein the dielectric film is a passivation layer for semiconductor and display devices.

18. An interlayer dielectric film for a semiconductor device comprising the dielectric film according to claim 14 adapted as a dual damascene copper interconnect.

19. An interlayer dielectric film for a semiconductor device comprising the dielectric film according to claim 15 adapted as a dual damascene copper interconnect.
